(19) United States
(12) Patent Application Publication
(10) Pub. No.: US 2008/0111597 A1
(43) Pub. Date: May 15, 2008

(54) Systems and Arrangements for Controlling a Phase Locked Loop

(75) Inventors: Hayden C. Cranford, Cary, NC (US); Marcel A. Kossel, Reichenburg (CH); Thomas H. Toifl, Zurich (CH)

Correspondence Address: IBM COPORATION (RTP);C/O SCHUBERT OSTERRIEDER & NICKELSON PLLC, 6013 CANNON MOUNTAIN DRIVE, S14, AUSTIN, TX, 78749, US

(73) Assignee: International Business Machines Corporation, Armonk, NY (US)

(21) Appl. No.: 11/558,108

(22) Filed: Nov. 9, 2006

(51) Int. Cl. H03L 7/06

(52) U.S. Cl. 327/156

(57) ABSTRACT

A high speed, low jitter phase locked loop (PLL) with feed forward phase frequency detection is disclosed. The phase frequency detector can include a phase difference sensor providing an output signal indicating a phase difference duration between a rising edge of a reference signal and a rising edge of a feedback signal. The apparatus can also include a lead lag sensor to provide an out put signal indicating when the reference signal leads the feedback signal. In addition, a steering logic module can be coupled to the output of the phase difference sensor and the lead lag sensor and the steering logic module can steer the phase difference duration signal to a first output when the reference signal leads the feedback signal, and can steer the phase difference signal to a second output when the reference signal lags the feedback signal.

### FIELD OF INVENTION

The present disclosure is in the field of communications and data processing, and further to the field of phase frequency detectors.

### BACKGROUND

Generally, each new generation of electronic equipment processes data at higher speeds and can communicate at higher speeds. Accordingly, clocks that run such electronic devices are required to operate at higher speeds in each new generation of devices. As clock speeds and data rates increase into the multi Gigahertz/Gigabit per second range, many design challenges arise. For example, jitter becomes a significant factor in clock signals because it can cause serious degradation in system performance. Jitter can occur as a “shaky” clock pulse or as a portion of a clock pulse that has a deviation, variation, or displacement from the desired shape. This deviation can come in the form of amplitude variations, timing variations, phase width variations and other variations where the pulse shape or the pulse timing is displaced from a desired time or amplitude.

Generally, clock signals are utilized in data processing systems and communication systems to synchronize data communication between circuits. One precision clock application, commonly referred to as clock and data recovery (CDR), requires system wide synchronization of circuits, and such circuits may be separated by a relatively long distance. New design requirements specify communication systems to operate in the multi-Gigabit range. It is a challenge to synchronize the timing of the receiver with the incoming data waveform at such high frequencies because a clean accurate clock signal is required for such synchronization. There are also many other applications for quality high speed clock signal. For example, radio frequency transmitters and receivers, navigation equipment and other serial link telecommunications equipment also typically require a robust clock signal.

Phase locked loops, (PLL) are often utilized to generate precision clock signals from a system clock and components within PLLs are often the source of jitter. PLLs typically have a voltage controlled oscillator (VCO) and a feedback loop controls the frequency of the VCO to provide and accurate clock output where the PLL maintains a constant phase angle relative to a reference signal. PLLs are widely used in communications for coherent carrier tracking and threshold extension, bit synchronization, and symbol synchronization. As mentioned above, PLL jitter becomes a significant problem at higher clock frequencies such as in the multi-Gigahertz range. PLLs with a narrow bandwidth in the feedback loop can significantly contribute to jitter because control signals in the feedback loop are limited in how fast they can respond to noise and other instability issues.

One way to generate a clock signal with very low jitter values for a serial link transmitter, is to choose a loop bandwidth value for the PLL that is as wide as possible in order to maximally suppress the jitter contribution of the VCO in the PLL. It is also desirable to utilize a very high reference frequency in the frequency feedback loop to suppress jitter because only a small feedback divider value is needed. However, such a high frequency typically prohibits using a conventional phase frequency detector (PFD) with an internal feedback loop in the PLL. The PFD is typically located as the input stage of a PLL and a traditional PFD cannot switch fast enough to accommodate this high frequency input and a high frequency feedback loop.

The most popular, traditional PFD used in PLLs typically includes two edge triggered resetable flip-flops together with an AND-gate in the reset path. This type of PFD is commonly referred to as “sequential phase-frequency detector.” Generally, edges of the incoming reference signal and the VCO feedback signal reset the PFD when both signals are high. The difference in time between the rising edges of the two signals is detected as phase difference, hence the name phase frequency detector (PFD). There are two significant problems associated with this type of traditional reset feedback.

First the internal feedback loop speed or frequency of the reset signal of the PFD limits the maximum operation speed of the PLL. Also there is a potential “dead zone” problem when the PLL is close to “phase-lock.” The system can be so close to phase lock that the feedback frequency does not have the resolution to achieve a lock and the output frequency will overshoot and undershoot the desired frequency. While the dead zone problem can be solved by inserting additional delay in the reset path, this introduces additional delays and increases the internal loop reset/speed problem which is difficult to solve even without this additional delay.

As stated above, a traditional PFD will incorporate two flip-flops with a combinational gate followed by a couple of inverters that introduce additional delay to eliminate the dead zone problem. Reset feedback can be provided from the UP and DOWN signal on the output of the PFD, to a reset input of both flip flops, such that the state of the flip flops can be reset. The time delay required for such a reset causes major issues with maximum stable operating speed of conventional or traditional PFDs.

Accordingly, due to this inherent problem with the feedback reset, PFD topologies without internal feedback loops have been proposed. For example in “A 2.5-10-GHz clock multiplier unit with 0.22-ps rms jitter in standard 0.18-mm CMOS,” written by R. van de Beek et al and published in IEEE J. Solid-State Circuits, vol. 39, pp. 1862-1871, November 2004, a PFD without a feedback loop is disclosed. Compared to the conventional sequential PFD, the proposed no feedback PFD topologies present a relatively expensive, unreliable and complicated solution. Such a solution requires a precise loop filter because the loop filter is utilized in the frequency detection (FD) path as a low pass filter, and in the phase detection (PD) path as high pass filter. Additionally, the FD typically has a limited frequency acquisition range, which is typically only ±25% of the desired voltage controlled oscillator (VCO) frequency. Such solutions have not achieved widespread usage because of these and other deficiencies. Accordingly, a reliable, low cost PFD that can operate at a high speed in a fast PLL to provide low jitter would be very useful.

### SUMMARY OF THE INVENTION

The problems identified above are in large part addressed by the systems, methods and media disclosed herein to provide a high speed, low jitter phase locked loop (PLL) with a feed forward phase frequency detector (PFD). In one embodiment, the apparatus includes a phase difference sensor having a first input, a second input, and an output. The output can provide a phase difference duration signal indicating a duration that a rising edge of a first signal on the first input is different than a rising edge of a second signal on the second input. The apparatus can also include a lead lag sensor having a first input coupled to the first input of the phase difference sensor, a second input coupled to the second input of the phase difference sensor and at least one output signal representing which of the first and second signal leads in time.

In addition, a steering logic module can be coupled to the output of the phase difference sensor and to the at least one output of the lead lag sensor. The steering logic module can steer the phase difference duration signal to a first output when the first input leads the second input signal, and can steer the phase difference signal to a second output when the first input lags the second input signal. The phase difference sensor can be implemented with an exclusive OR gate, the lead lag sensor can be implemented with a D flip-flop, and the steering logic can be implemented with two AND gates.

In another embodiment, a phase locked loop system is disclosed. The system can include a feed forward phase frequency detector to receive a reference signal and to receive a loop feedback signal, and to provide a positive phase magnitude output signal on a first output and a negative phase magnitude output signal on a second output. The system can also include a charge pump coupled to the first and second feed forward phase frequency detector output to accept the positive and negative phase magnitude output signal. The charge pump can provide a positive variable current output in response to the positive phase magnitude output signal and can provide a negative variable current in response to the negative phase output signal of the feed forward phase frequency detector.

A local oscillator or VCO can be coupled to the charge pump and configured to oscillate at a particular frequency. The VCO can change frequency in response to the variable current output of the charge pump which can be converted into a control voltage for the VCO utilizing a loop filter. The local oscillator can provide a system output clock signal that is synchronized with the reference signal and feedback can be obtained from this signal and delivered back to the phase frequency detector.

A two stage PLL system is also disclosed. In the two stage system, a traditional PLL with a traditional PFD can be utilized in the first stage. The traditional PLL can help to reduce most of the jitter present on the reference frequency input by utilizing a narrow loop bandwidth together with a VCO with a high quality factor. The traditional PFD can receive a reference signal and a second loop feedback signal, and provide a phase difference-phase magnitude output signal to a second charge pump. The second charge pump can be coupled to the traditional PFD to accept the phase difference-phase magnitude output signal and provide a current output in response to the phase difference-phase magnitude output signal. A second local oscillator can be coupled to the second charge pump and configured to change frequency of a second local oscillator in response to the current output of the second charge pump. The second local oscillator can provide feedback to the traditional PFD and can provide a relatively high reference frequency to the feed forward PFD of the second stage PLL. The second stage of the PLL can have a very wide loop bandwidth to optimally suppress the jitter generation of the VCO, which can a wideband, low quality factor type oscillator that can cover multiple frequency bands.

In yet another embodiment, a method for operating a phase locked loop is disclosed. The method can include receiving a reference signal and a feedback signal, producing a phase difference pulse width in response to a time duration of a phase difference between the reference signal and the feedback signal. The phase difference signal can be steered to a first output if the reference signal leads the feedback signal, and steered to a second output if the reference signal leads the feedback signal. The reference signal can have a relatively high frequency as received from an output of a first stage phase locked loop.

### BRIEF DESCRIPTION OF THE DRAWINGS

Aspects of the invention will become apparent upon reading the following detailed description and upon reference to the accompanying drawings in which, like references may indicate similar elements:

FIG. 1 depicts a block diagram of two stage phase locked loop (PLL);

FIG. 2 illustrates a block diagram of feed forward phase frequency detector (FFPFD);

FIG. 3 depicts a timing/signaling graph for the block diagram of FIG. 2;

FIG. 4 shows a graph of a transfer function of a feed forward phase detector;

FIG. 5 depicts a block diagram of a feed forward phase detector that can control a phase locked loop; and

FIG. 6 depicts a flow diagram of operation of a feed forward phase frequency detector.

### DETAILED DESCRIPTION OF EMBODIMENTS

The following is a detailed description of embodiments of the disclosure depicted in the accompanying drawings. The embodiments are in such detail as to clearly communicate the disclosure. However, the amount of detail offered is not intended to limit the anticipated variations of embodiments; on the contrary, the intention is to cover all modifications, equivalents, and alternatives falling within the spirit and scope of the present disclosure as defined by the appended claims. The descriptions below are designed to make such embodiments obvious to a person of ordinary skill in the art.

While specific embodiments will be described below with reference to particular configurations of hardware and/or software, those of skill in the art will realize that embodiments of the present disclosure may advantageously be implemented with other equivalent hardware and/or software systems. Aspects of the disclosure described herein may be stored or distributed on computer-readable media, including magnetic and optically readable and removable computer disks, as well as distributed electronically over the Internet or over other networks, including wireless networks. Data structures and transmission of data (including wireless transmission) particular to aspects of the disclosure are also encompassed within the scope of the disclosure.

To generate a clock signal with very low jitter utilizing phase locked loop (PLL), the loop bandwidth of the PLL should be chosen as wide as possible. Accordingly, it is advantageous to design a PLL such that the PLL can accommodate a very high frequency input reference signal. The input stage of PLL is typically a phase frequency detector (PFD) and traditional PFDs have serious speed limitations. Thus, traditional PLLs with traditional phase frequency detectors (PFDs) will not operate at frequencies that meet today's demands. A specialized fast PFD is disclosed herein that can switch at higher speeds allowing PLLs to operate at ever increasing speeds.

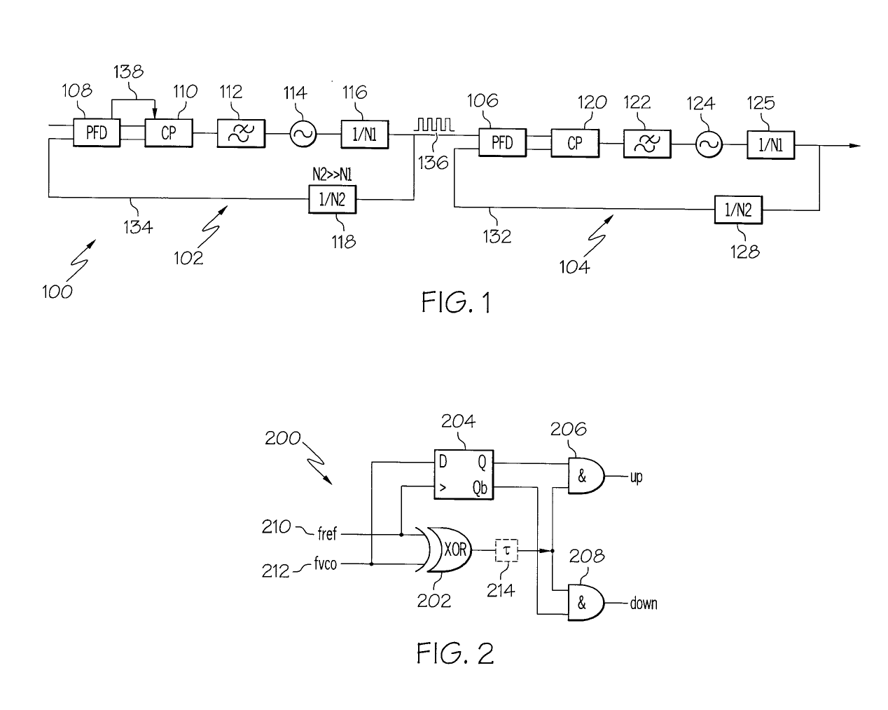

Referring to FIG. 1, a two stage PLL 100 is illustrated. In one embodiment, the first stage 102 is similar to the second stage 104 with the exception that the second stage 104 can utilize a feed forward phase frequency detector (FFPFD) 106 in accordance with the present disclosure. The FFPFD 106 can operate at frequencies that are magnitudes higher the traditional PFDs with feedback.

The first phase locked loop 102 can include a phase frequency detector (PFD) 108, a gain control module 138, a charge pump 110, a small band width filter 112, a local oscillator or voltage controlled oscillator (VCO) 114, and a 1/N1 frequency divider 116. In operation, a low frequency reference signal can be provided to the input of the PFD 108 from an outside source, and based on the detected phase difference between the reference signal and the feedback loop signal, the PFD 108 can drive the charge pump 110. The output signal of the charge pump 110 can be fed to the filter 112 and the filtered signal can be utilized to control the clock frequency output signal of the VCO 114. The output signal of the VCO 114 can be provided to frequency divider 116. The output signal of the VCO 114 can again be divided by the 1/N2 divider in the feedback loop 134 and this signal can be returned to the PFD 108 as feedback such that the first stage 102 can provide a precise, robust high frequency clock signal 136 to the second stage 104. The VCO 114 can be a high frequency oscillator with a small inductance, that provides a high Q value and a small loop bandwidth can be implemented by the PLL 102. Such a small loop bandwidth allows the PLL to be stable even when driven with a poor quality reference frequency 130 at the input of the first stage 102 of the two-stage PLL 100.

The second stage 104 of the PLL can include a feed forward phase frequency detector (FFPFD) 106, a charge pump 120, a filter with a high band width 122, a local oscillator or VCO 124, and a (1/N1) frequency divider 125. In operation, the high frequency reference signal 136 from the output of the first stage 102 can be fed to the input of the FFPFD 106 and based on the phase difference detection between the feedback loop signal 132 and the high frequency reference signal 136, the FFPFD 106 can drive an error signal to the charge pump 120, and this error signal will “eventually” correct the oscillation frequency of the VCO 124 when a phase difference is detected at the input of the FFPFD 106. The output signal of the charge pump 120 can be fed to the filter 122 and the filtered signal can control the operating frequency of the local oscillator 124 to provide a signal to the divider 125 before the signal is provided as a synchronized clock signal output. The clock signal can be divided by the 1/N2 divider 128 and provided as feedback to FFPFD 106 such that the output of the second stage PLL 104 can provide a stable “jitter free” high frequency clock signal on its output for use by many different types of operational circuits.

As stated above, in one embodiment, the PFD 108 in the first stage 102 can be a conventional PFD that can only accept a relatively low reference signal frequency on its input. However, the first stage 102 can produce an output clock signal having a reference frequency of greater than five (5) Gigahertz. The second stage PFD 104 can accept this relatively high frequency signal from the first stage 102 and can utilize a relatively high frequency in its feedback loop 132 because the second stage 104 utilizes among other things, feed forward control on the FFPFD 106. The FFPFD 106 of the second stage 104 can accept high frequency reference and feedback signals and detect the difference in phase between these signals and provide an accurate output signal representing a difference in phase between these two signals. Thus, in operation, the FFPFD 106 can measure the phase difference between the reference signal 136 provided by the first stage 102 and the divided VCO signal 132 on the feedback loop 132 and provide a pulse having a duration that is commensurate with the phase difference of signals 132 and 136.

The reference signal on the input of the PLL 100 is often a “global” system clock that is distributed to the majority of systems that are co-located with the PLL 100 on the same chip or integrated circuit. The first stage 102 can be impedance matched to the interconnection or wiring of the clock distribution network such that the first stage 102 does not significantly load or alter the system reference signal. The low frequency nature of the first stage 102 is conducive to providing a low propagation loss or minimal loading on the global clock distribution network. Generally, first stage PLL 102 will not load the system reference signal and can “clean up” jittered and other noise often present with the system reference signal 130.

It can be appreciated that not only the insertion loss measured by the reflection scattering parameter of the PLL's input stage contributes to system clock loading but the propagation loss at higher frequencies cause the clock distribution wiring can require that the system clock be routed to only ‘low’ frequency PLLs across larger distances (several millimeters or centimeters). Otherwise, the amount of power consumed by the clock distribution system would have to be prohibitively high to overcome the propagation losses that are present on transmission lines at very high frequencies.

Thus, the VCO's 114 and 124 can have significantly different attributes. While VCO 114 can have a high Q and hence be a narrow band oscillator to perform a “clean up” function on the reference frequency signal 130, VCO 124 can have a wideband and hence a low Q to provide a high frequency and stable clock signal when it has a clean input signal from the first stage 102. VCO 124 will typically produce more jitter than VCO 114, and thus, VCO 124 can support the wide loop bandwidth present in the second stage 104 of the PLL system 100. Generally in PLLs suppressing the jitter of a “noisy” reference frequency at an input and providing an output having a wide range of clock frequencies are considered mutually exclusive design options for a single stage PLL, because a stable wide range output is virtually impossible with a noisy signal on the input of the PLL. Thus, cascading two PLLs with distinct advantages can solve these problems and provide an improved clock signal.

One benefit of utilizing a higher speed internal feedback loop in the second stage 104 is that the maximum stable operating speed of the PLL can be significantly increased. This faster control loop speed can significantly reduce the jitter and virtually eliminate the dead zone properties that occur when a PLL is close to achieving a phase-lock. Accordingly, improved control properties can be utilized by the disclosed high speed FFPFD 106 via a high speed control loop and a high speed FFPFD.

As with almost all control loops, the bandwidth of loop 132 is limited by the stability of the second stage 104 of the PLL. In the present disclosure, the stability of the first stage 102 with respect to its input reference frequency is typically not an issue because the first stage control loop 134 has a relatively low frequency with a relatively small bandwidth. However, the second stage 104 of the cascaded PLLs has a much greater bandwidth operating at a much higher frequency.

Accordingly, the input reference frequency 130 can have a low reference frequency, and the first stage 102 can filter the reference frequency 130 utilizing a small or relatively slow loop 134 or narrow loop bandwidth. For example, the bandwidth of the first PLL 102 can be on the order of a few kHz. The second stage 104 of the PLL system can reduce the VCO jitter by utilizing a relatively wide loop bandwidth, and utilizing a relatively high reference frequency provided by the output of the first stage PLL 102. For example, the loop bandwidth of the second PLL 104 may range from a few tens of MHz up to about one tenth of the PLL's output frequency. It has been determined that the second stage 104 can effectively operate with a feedback loop running at a frequency of one tenth of the PLL's output frequency and maintain adequate system stability. If the PLL of the present disclosure is utilized for clock generation in a clock and data recovery application or anther digital communication system, the frequency of the feedback loop 132 may operate at a couple of GHz. However, the actual frequency of the feedback loop can depend on the target data speed. The gain module 138 can receive a signal from the PFD 108 and provide an adjustable gain signal to the charge pump 110.

Traditional high speed PFDs are relatively bulky and complex and the FFPFD 106 disclosed can function with less components than the traditional sequential PFDs and take up less wafer space than traditional PFDs. One additional benefit of the FFPFD 106 is that the FFPFD 106 can provide a phase detector gain that is twice as high as that of traditional PFDs. Another benefit is that the FFPFD 106 does not have a limited frequency acquisition range as is the case with traditional PFDs.

Referring to FIG. 2, a feed forward phase frequency detector (FFPFD) 200 is disclosed. The disclosed FFPFD 200 could be effectively utilized in the second stage PLL 104 of FIG. 1. The FFPFD 200 can include a phase difference sensor embodied herein as an exclusive OR (XOR) gate 202, a lead lag sensor embodied as a D-flip-flop 204, a time delay module 214, and a steering module, embodied by two AND-gates 206 and 208.

In operation, the XOR-gate 202 can measure the phase difference between the reference signal (F_{REF}) 210 and the divided VCO signal (F_{VCO}) 212 and provide a phase difference duration signal on its output indicating a duration that a rising edge of F_{REF} 210 leads or lags F_{VCO} 212. The D-flip flop 204 can have two output signals, one providing a logic high when F_{REF} 210 leads F_{VCO} 212, and the other providing a logic high when the F_{REF} 210 lags the F_{VCO} 212.

The XOR-gate 202 can accept a reference signal F_{REF} 210 in the range of several or tens of gigahertz and can accept the feedback loop signal F_{VCO} 212 from the output of a VCO. The XOR-gate 202 can produce a logic high output when F_{REF} 210 and F_{VCO} 212 have unequal logical levels or are at different states. This XOR logic high output indicates a period of time when a phase difference exits between F_{REF} 210 and the F_{VCO} 212. The D-flip-flop 204 can sense or determine whether the rising edge of the divided VCO signal F_{VCO} 212 leads or lags the rising edge of the reference signal F_{REF} 210. Thus, the D-flip-flop 204 can produce a logic high output on a Q output if F_{REF} 210 leads F_{VCO} 212 and the D-flip-flop can produce a logic high output on a Qb when F_{VCO} 210 leads F_{REF} 212. The outputs of the D flip-flop 204 can then be utilized to control or activate the AND-gates 206 and 208.

When the Q output of the D-flip flop 204 is high, the Qb output of the D-flip flop 204 will be low and vise-versa. Thus, the output of the XOR-gate 202 can provide a pulse representative of the time when a phase difference exists between F_{REF 210} and F_{VCO} 212, while the D-flip flop 204 can provide a steering signal representing whether F_{VCO} 212 leads F_{REF} 210 on a first output or a second steering signal when F_{VCO} 212 lags F_{REF} 210. Accordingly, the signals at the output of AND-gate 206 can provide a lead signal magnitude indicator or a signal to increase the VCO frequency in the loop by a specific amount (time durations) on its output. Likewise the signals at the output of AND-gate 208 can provide a lag signal magnitude indicator or a signal to decrease the VCO frequency in the loop by a specific amount (time durations) on its output.

One additional feature provided by the FFPFD 200 is that the FFPFR 200 does not have an internal feedback loop such as those required by traditional sequential PFDs. As can be appreciated by understanding the operation of the flip-flop and logic gates that are utilized to implement the FFPFD 200 the disclosed PFD 200 has no internal feedback path and no reset signal is required. The traditional feedback loop limitation found in traditional PFDs has been eliminated and the disclosed FFPFD 200 can operate at high speeds because of its improved frequency response, as all signals are fed forward. The disclosed FFPFD 200 can accept a very high reference frequency (F_{REF}) at its input and remain stable because there are no inner feedback loops that insert reset delays that often “de-synchronized” the systems and cause instability. Hence, the second PLL 104 in the system 100 can be operated with a very wide loop bandwidth. Such a wide bandwidth is one way to provide significant suppression of VCO jitter.

Additionally, the disclosed FFPFD 200 has fewer parts, takes up less space and is easier to manufacture than traditional PFDs. FFPFD 200 also allows for improve simulation timing in the design phase as the numerous unknown switching delays, that must be accommodated for in designs utilizing traditional PFDs are virtually eliminated or can be more tightly predicted in designs utilizing the disclosed FFPFD 200. Eliminating such unknown delay allows the actual signal throughput of the system to be greatly increased.

The FFPFD 200 can also provide improved or “faster” lock-in times on start up because the XOR-gate 202 can measure the phase difference at both the rising and falling edge of reference signal 210. This feature is similar to using a conventional PFD with double-edge triggered flips-flops however the FFPFD 200 has a greatly reduced parts count as compared to this conventional design because the FFPFD 200 can perform as a conventional double-edge triggered PFD without double-edge triggered flip-flops and without an internal reset feedback loop. It can be appreciated that the output of the FFPFD 200 provides a unipolar output. Thus, each output has one signal. This unipolar control signal represents simply, one of two states: on or off; 1 or 0 wherein a traditional double edge flip flop commonly has a tri-state output that has a high impedance output state that often allows the downstream circuit controlled by the traditional PFD to drift.

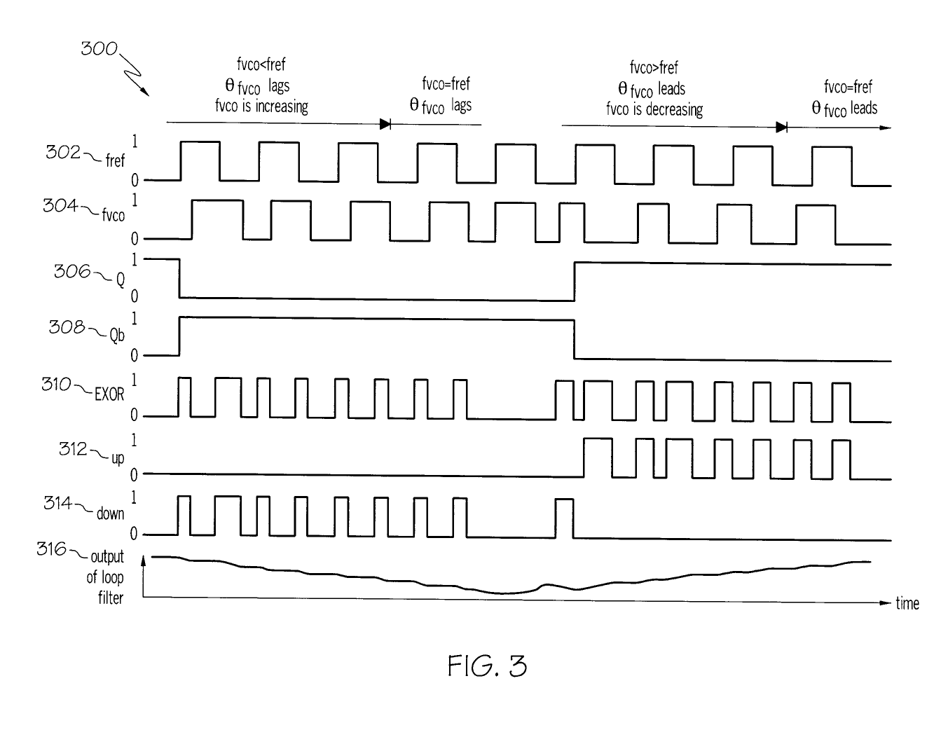

Referring to FIG. 3, a timing/signaling diagram 300 of signals accepted by, and provided by the FFPFD in FIG. 2 is disclosed. As stated above, in operation, the output of the XOR-gate 310 can be at a logic high during the time interval where the reference signal (F_{REF}) 302 and the VCO loop signal (F_{VCO}) 304 are at different states. Thus, an XOR-gate can detect and indicate a period of time where a phase difference exits between F_{REF} 302 and F_{VCO} 304 as indicated by signal 310. Notice that XOR signal varies in width or duration depending on the time which the F_{REF} 302 and F_{VCO} 304 signal are at different states. When the Q output of the flip-flop, signal 306 is at a logic high, this indicates that F_{VCO} 304 lags F_{REF} 302. This is illustrated by viewing the first four clock signals and comparing F_{VCO} 302 to F_{VCO} 304 and to Q signal 306.

The Qb signal 308 is the compliment of the Q signal 306, such that when Qb is at a logic high, Q 306 will be at a logic low and vise-versa. When Qb is at a logic high this can indicate that the leading edge of F_{VCO} 304 leads the leading edge of F_{REF} 302 and when Q 306 is at a logic high this can indicate that the leading edge of F_{VCO} 304 lags the leading edge of F_{REF} 302. Such mutually exclusive operation or logic status can be seen by comparing signals Q 306 and Qb 308. Signal Q 306 can drive or activate a first AND gate and signal Qb 308 can drive or activate a second AND gate. Signals 312 and 314 outputs of the first and second AND gates where one AND gate provides an “Up” control signal and one AND gate provides a “Down” output, steering the detected delay time depending on the lead lag detection. Signal 316 illustrates the output of the loop filter and how it can have a lower value when F_{REF} 302 and F_{VCO} 304 are “in sync” and the PLL is locked.

The timing diagrams of the FFPFD in FIG. 3 depict different input and output (I/O) and internal and external FFPFD signals for a decreasing and increasing VCO frequency (F_{VCO} 304) which either leads or lags the reference frequency (F_{REF} 302). As depicted by the text at the top of the diagram 300 during the first three pulses from the left of the graph 300 F_{VCO} 304<F_{REF} 302 or F_{VCO} 304 has a larger duration, and F_{VCO} 304 lags F_{REF} 302. In the next two pulses, (pulses four and five) F_{VCO} 304=F_{REF} 302 or they have the same duration and F_{VCO} 304 lags F_{REF} 302. As depicted by the fifth pulse from the left of the diagram 300, the VCO in the PLL has been controlled such that F_{VCO} 304 is synchronize or in phase with F_{REF} 302. Thus, output of the loop filter 316 will approach zero.

In pulses 6 through 8 F_{VCO} 304>F_{REF} 302 and F_{VCO} 304 leads F_{REF} 304 and in the last two pulses F_{VCO} 304=F_{REF} 302 and F_{VCO} 304 leads F_{REF} 302. Based on the abovementioned leads-lags configurations and different pulse widths of four different possible input phenomena to the PFD, the Up 312 and Down 314 signals can be provided to a VCO controller such that the VCO can provide an output signal that is in phase or aligned with the reference signal 302 on the PLL input.

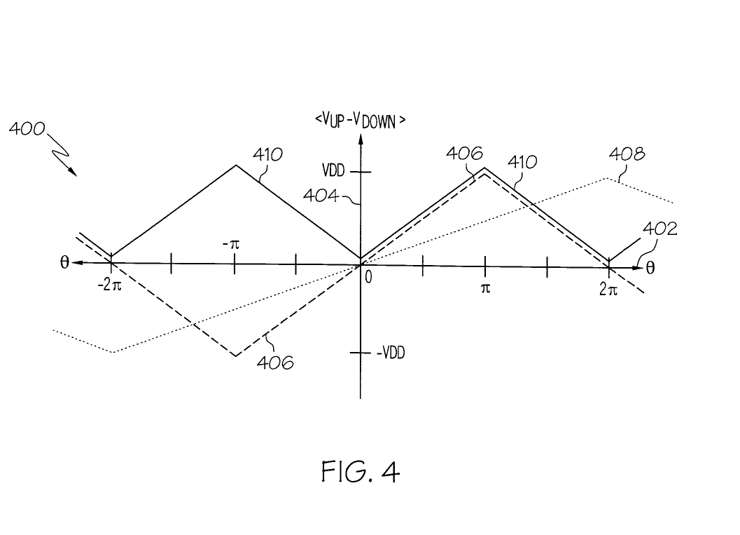

Referring to FIG. 4, a graph 400 of transfer functions, (i.e. input on the x-axis and output on the y-axis), of three different types of PFDs are disclosed. The phase difference in radians between F_{REF} and F_{VCO} on the input of the PFDs is provided on the horizontal axis 402. In the right half plane F_{VCO} lags F_{REF} and in the left half plane F_{VCO} leads F_{REF}. The difference of the output voltages V_{UP}−V_{DOWN} between the “UP” and “DOWN” ports of the PFDs (or possibly a single port) are provided on the vertical or y-axis 404, where the UP port will provide signals that are above the x axis and the DOWN port will provide the signals that are below the x axis.

The dark dashed line can depict a transfer function or output signal 406 provided by the disclosed FFPFD. The solid line can indicate an output signal 410 of a traditional XOR based phase detector, and light dashed line can depict an output signal 408 of a traditional sequential PFD. When comparing the transfer functions provided by the three output signals 406, 408 and 410 it can be appreciated that output signal 406 of the disclosed FFPFD has a larger gain “KD” than the output signals 408 and 410 of the other two conventional PFDs. Thus, the disclosed FFPFD will have an increased loop filter output voltage. Such a gain will assist the disclosed fast PLL in achieving a phase lock at a much faster rate than PLL utilizing conventional PFDs.

Such traditional phase detectors typically consists of a simple XOR gate, which does not discriminate between UP and DOWN directions and will only provide a positive signal on a single output or will only provide a single unipolar output based on phase difference detection only. Therefore, the vertical axis 404 must be interpreted in this case as being V_{OUT} on axis 404 and not two different signals (V_{UP}−V_{DOWN}) as provided by the disclosed FFPFD. The V_{UP}−V_{DOWN} output signals 406 and 408 as well as a V_{OUT} (a single signal) in the case of output signal 410 can be an average value obtained over a reference frequency period.

As can be appreciated by analyzing the graph 400, that the output of traditional sequential PFD represented by output signal 408 and the disclosed FFPFD represented by output signal 406 are able to provide separate signals because they discriminate between the UP and DOWN or lead lag direction. Thus, output signals 406 and 408 can provide a positive signal when a “lead” is detected and can provide a positive signal on a separate line when a “lag” is detected. However, the positive down signals can be utilized to slow the oscillation frequency of the VCO. It should be noted that the XOR gate phase detector output signal 410 shown for comparison purposes is unable to perform this “UP-DOWN” or lead-lag discrimination. This behavior is visible in the left-half plane of the graph 400 where output signal 410 is symmetric or balanced with respect to the vertical axis, while “UP-DOWN” based output signals 406 and 408 illustrate PFDs that are not symmetric with the Y-axis because they are able to discriminate between the lag and lead phase constellations. Hence the UP-DOWN configuration of output signals 406 and 408 are depicted symmetric with respect to both the x-axis and the y-axis or the origin of the graph 400.

The disclosed FFPFD includes an XOR gate enhanced by an additional D-flip flop and a steering logic consisting of two AND gates. With these additional improvements, or this novel arrangement, the operation of a simple XOR phase detector can be transformed into a PFD having an output signal such as output signal 406 which depicts a possible output of the disclosed FFPFD.

It can be appreciated that the disclosed FFPFD can be configured in many ways such that the direction or polarity of the output signal (for example the discrete UP or a DOWN signal) can be activate based on either “lead or lag” detection. Thus, depending on the interconnection within the FFPFD, the polarity of the output can be dictated by how the FFPFD is internally interconnected, such that different output polarities can be created based on a design choice of detectable leads and lags of a particular signal. For example, the UP-DOWN direction can be defined by the way F_{REF} and F_{VCO} are connected to the D and Clk inputs of the D-flip flop (that is, F_{VCO} at D and F_{REF} at Clk or vice versa).

The direction or polarity of the FFPFD output can also be configured based on the tuning characteristic of the VCO, which can either be positive or negative (i.e. different VCO will increase in frequency or decreases in frequency with an increasing or decreasing input current or, or loop filter polarity). The VCO tuning characteristics may also be dependent on the polarity of the charge pump because the UP and DOWN signals of the PFD can either be connected to current sinks or current sources in the charge pump. As stated above, there are several degrees of freedom with respect to what input phenomena provides what signal polarities. However, the UP-DOWN control outputs can be matched, such that the PLL is not driven to a voltage rail by the FFPFD. One additional design flexibility includes altering the duration of the UP and DOWN pulses as defined by the properties of the XOR gate in the FFPFD.

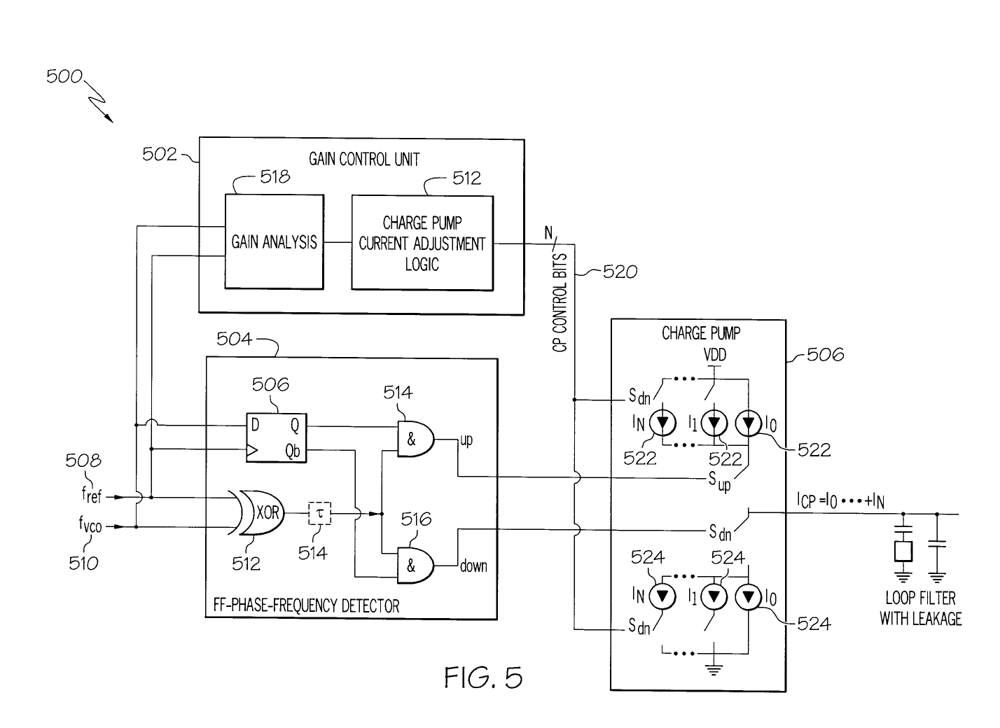

Referring to FIG. 5, a portion of a phase locked loop system 500 is disclosed. The system 500 can include a feed forward phase frequency detector (FFPFD) 504, and a gain control unit 502 configured in a parallel configuration with the FFPFD 504. The FFPFD 504 and the gain control unit 502 can drive a multistage push-pull charge pump 506. However, this is merely one embodiment as the FFPFD 504 could drive many other types of circuits without parting from the scope of the present disclosure. Other circuits such as a voltage divider network, a digital to analog converter or a conventional charge pump are other examples of circuits that could utilize such an output from the FFPFD 504. The gain control unit 502 can include a gain analysis module 518 and a charge pump current adjustment module 512.

The FFPFD 504 can perform phase detection on two incoming signals, F_{REF} 510 and F_{VCO} 508. As with previously described embodiments, the FFPFD 504 can be implemented with sequential logic that receives and compares two input signals, F_{REF} 510 and F_{VCO} 508. The gain control unit 502 can have two inputs that are coupled in parallel with the inputs of the FFPFD 504 such that the gain control unit 502 receives F_{REF} 510 and F_{VCO} 508. An “UP” or a “DOWN output of the FFPFD 504 can be utilized to drive a “frequency increasing side” of the charge pump or a “frequency decreasing side” of an oscillator controller or charge pump 506. This way, current can be sourced by current sources 522 (increasing the VCO frequency) or sunk by current sinks 524 (decreasing the VCO frequency) based on the desired direction of the phase shift in the PLL. The output of the gain control unit 502 can control the amount of current that will be sourced or sunk by activating the appropriate number of current sources/current sinks (i.e. 522 and 524) in the charge pump 506. Accordingly, when more current sources are activated a stronger correctional signal will be sent to the VCO.

As described above, the sequential logic of FFPFD 504 can be implemented by a D-flip-flop 506 that senses whether a rising edge of a F_{VCO} signal 508 leads or lags the rising edge of the reference signal F_{REF} 510. The outputs of the D-flip-flop 506 can then be “steered” responsive to the output of the XOR-gate 512 (which gives either an early or late signal) to provide either an UP or DOWN output by means of two parallel AND-gates 514 and 516.

Referring briefly back to FIG. 4 dashed line 406 illustrates that the time averaged voltage on the output of the FFPFD 504 can swing between −V_{DD} and +V_{DD}. The V_{UP}−V_{DOWN} “differential” signal or discrete signals can then be connected to separate circuits such as current source circuits 522 and current sink circuits 524. When the reference signal 508 lags the VCO signal 510 from O to −π, the output of the FFPFD 504 is illustrated in the left half plane of the graph 400 as the “Down” output will is illustrated as a negative signal in accordance with the XOR-gate 512 characteristics described above. This desired effect (i.e. positive or negative signal) is generated from the AND gates 514 and 516 of the FFPFD 504, which steer the phase detection difference duration signal based on lead-lag information as detected by the D-flip-flop 506 to provide activate either the UP or the DOWN output.

Additionally, as described it can be appreciated that the FFPFD 504 has a gain that is twice as high as conventional PFDs. This is illustrated by the slope of line 406 in FIG. 4 where the slope of the output signal 406 is approximately two times the slope of line 408. In one embodiment, the gain of the FFPFD 504 can be described as KD=V_{DD}/π where the traditional PFD gain can be described as KD1=V_{DD}/2π. Generally, the FFPFD 504 has many of the same characteristic as a traditional double-edge triggered PFD without physically requiring double-edge triggered flip-flops. The higher gain of the FFPFR 504 effect occurs because the XOR-gate, 512 senses the phase difference at both the rising and falling edges of the reference signal, whereas traditional flip flop type detectors detect differences in either the rising or falling edges but not both.

As discussed above, the FFPFD 504 can have twice the gain as typical PFDs. In some implementations the increased gain is desirable, however, in other implementations (i.e. a high frequency noisy environment) a designer may want to reduce the gain of the FFPFD 504 or transfer the gain of the FFPFD 504 forward to another stage of the PLL such as the charge pump of the VCO 506. Thus, in one embodiment, the gain control unit 502 can be utilized to control the gain of the FFPFD 504 or to transfer the gain forward in the PLL loop.

The gain control unit 502 can make a gain analysis based on whether the loop is locked, on whether there is excessive jitter and how, where, and why the jitter is occurring. Based on the determination of the gain analysis module 518, the charge pump current adjustment module 512 can send control signals to the charge pump 506 possibly on an eight bit wide bus 520. Many other gain analysis, gain control, gain forwarding and gain insertion could also be utilized with the FFPFD 504 and the FFPFD 504 could be utilized in applications other that a PLL application where the FFPFD 504 drives circuits other than the one(s) depicted and described herein. Thus, the operations and applications of the FFPFD 504 should not be limited to the disclosed embodiments and descriptions.

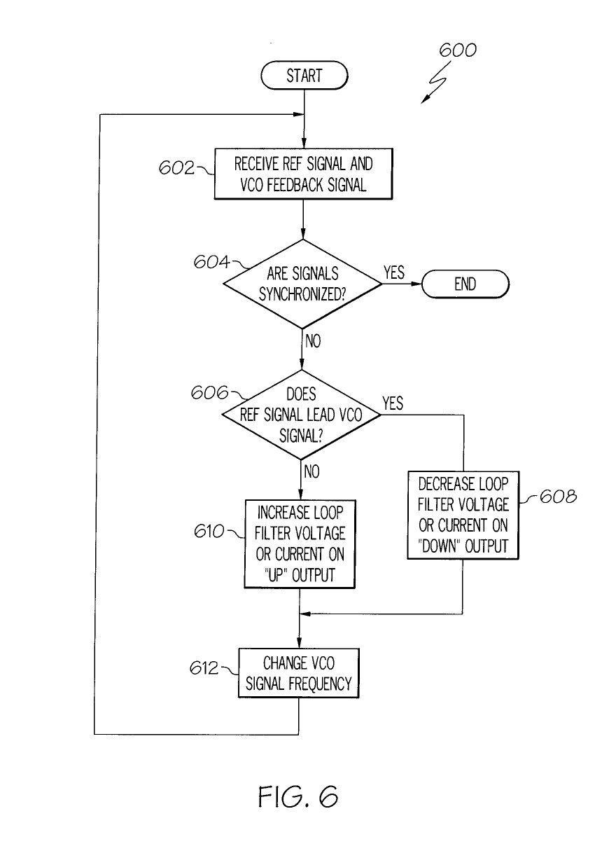

Referring to FIG. 6 a flow diagram 600 for controlling a feedback loop of a phase frequency detector is disclosed. Initially, a reference signal and a voltage controlled oscillator (VCO) signal can be provided to the input of a phase frequency detector as illustrated by block 602. As illustrated by decision block 604, the phase frequency detector can determine if the reference signal and the VCO signal have different “logic” values or have rising and falling edges that occur at a “different times.” If the signals have the same logic state, then the loop is synchronized or locked and the process can end. If the reference signal and the VCO signal have different logic states or have rising edges that do not occur at the same time, this is an indication that the loop is not synchronized or is not phase locked. Such a determination can be made by an exclusive OR gate or other lock detection hardware.

As illustrated by decision block 606, it can be determined if the VCO signal leads the reference signal. When the VCO signal leads the reference signal, then the loop filter voltage can be decreased, as illustrated by block 610. When the VCO signal lags the reference frequency, the loop filter voltage can be increased as illustrated by block 608 or vice versa if the tuning characteristics of the VCO are defined differently. The VCO frequency can be adjusted with the increased or decreased loop voltages as illustrated in block 612 and the process can revert back to block 604 where the reference signal and the altered VCO signal are again received by the PFD and compared to determine a phase difference.

Each process disclosed herein can be implemented with a software program. The software programs described herein may be operated on any type of computer, such as personal computer, server, etc. Any programs may be contained on a variety of signal-bearing media. Illustrative signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet, intranet or other networks. Such signal-bearing media, when carrying computer-readable instructions that direct the functions of the present invention, represent embodiments of the present disclosure.

The disclosed embodiments can take the form of an entirely hardware embodiment, an entirely software embodiment or an embodiment containing both hardware and software elements. In a preferred embodiment, the invention is implemented in software, which includes but is not limited to firmware, resident software, microcode, etc. Furthermore, the invention can take the form of a computer program product accessible from a computer-usable or computer-readable medium providing program code for use by or in connection with a computer or any instruction execution system. For the purposes of this description, a computer-usable or computer readable medium can be any apparatus that can contain, store, communicate, propagate, or transport the program for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid state memory, magnetic tape, a removable computer diskette, a random access memory (RAM), a read-only memory (ROM), a rigid magnetic disk and an optical disk. Current examples of optical disks include compact disk-read only memory (CD-ROM), compact disk-read/write (CD-R/W) and DVD. A data processing system suitable for storing and/or executing program code can include at least one processor, logic, or a state machine coupled directly or indirectly to memory elements through a system bus. The memory elements can include local memory employed during actual execution of the program code, bulk storage, and cache memories which provide temporary storage of at least some program code in order to reduce the number of times code must be retrieved from bulk storage during execution.

Input/output or I/O devices (including but not limited to keyboards, displays, pointing devices, etc.) can be coupled to the system either directly or through intervening I/O controllers. Network adapters may also be coupled to the system to enable the data processing system to become coupled to other data processing systems or remote printers or storage devices through intervening private or public networks. Modems, cable modem and Ethernet cards are just a few of the currently available types of network adapters.

It will be apparent to those skilled in the art having the benefit of this disclosure that the present invention contemplates methods, systems, and media that provide a phase frequency detector. It is understood that the form of the invention shown and described in the detailed description and the drawings are to be taken merely as examples. It is intended that the following claims be interpreted broadly to embrace all the variations of the example embodiments disclosed.

What is claimed is:

1. An apparatus comprising:
a phase difference sensor having a first input, a second input and an output, the output to provide a phase difference duration signal, indicating a duration between a rising edge of a first signal on the first input and a rising edge of a second signal on the second input;
a lead lag sensor having a first input coupled to the first input of the phase difference sensor, a second input coupled to the second input of the phase difference sensor and at least one output to provide an output signal representative of which of the first and second signal leads in time; and
a steering logic module coupled to the output of the phase difference sensor and to the at least one output of the lead lag sensor, the steering logic module to steer the phase difference duration signal to a first output when the first signal leads the second signal and to steer the phase difference signal to a second output when the first signal lags the second signal.

2. The apparatus of claim 1, wherein the phase difference sensor provides a second phase difference duration signal, indicating a duration between a rising edge of a second signal on the first input and a rising edge of a first signal on the second input.

3. The apparatus of claim 1, wherein the first input signal has frequency greater than two gigahertz.

4. The apparatus of claim 1, wherein the phase difference sensor comprises an exclusive OR gate.

5. The apparatus of claim 1, wherein the lead lag sensor comprises a D flip-flop.

6. The apparatus of claim 1, wherein the steering logic comprises two AND gates.

7. A phase locked loop system comprising:
a feed forward phase frequency detector to receive a reference signal and a loop feedback signal, and to provide a positive phase magnitude output signal on a first output and a negative phase magnitude output signal on a second output;
a charge pump coupled to the first and second feed forward phase frequency detector output to accept the positive and negative phase magnitude output signal and to provide a positive variable current output in response to the positive phase magnitude output signal and to provide a negative variable current in response to the negative phase output signal; and.
a local oscillator coupled to the charge pump, the local oscillator configured to oscillate at a frequency, and configured to change frequency in response to the variable current output of the charge pump, the local oscillator to provide a clock signal feedback to the feed forward phase frequency detector and to provide a system output clock signal that when the system is phase locked will provide a synchronized output signal.

8. The system of claim 7, further comprising a first frequency divider coupled to the output of the local oscillator to divide an output frequency of the local oscillator to create a system output clock with a lower frequency.

9. The system of claim 7, further comprising a second frequency divider coupled to an output of the first frequency divider and to the feed forward phase frequency detector to divide the frequency of the clock signal feedback.

10. The system of claim 7, further comprising a filter coupled to the charge pump and to the oscillator.

11. The system of claim 7, further comprising:
a phase frequency detector to receive a reference signal and to receive a second loop feedback signal, and to provide a phase difference-phase magnitude output signal;
a second charge pump coupled to the phase frequency detector to accept the phase difference-phase magnitude output signal and provide a current output in response to the phase difference-phase magnitude output signal; and
a second local oscillator coupled to the second charge pump and configured to change frequency in response to the current output of the second charge pump, the second local oscillator to provide feedback to the phase frequency detector and to provide the reference frequency to the feed forward frequency detector.

12. A method for operating a phase locked loop comprising:
receiving a reference signal and a feedback signal with a feed forward phase frequency detector;
producing a phase difference pulse width in response to time duration of a phase difference between the reference signal and the feedback signal;
steering the phase difference signal to a first output, if the reference signal leads the feedback signal; and
steering the phase difference signal to a second output, if the reference signal leads the feedback signal.

13. The method of claim 12, further comprising receiving the reference signal from a first stage phase locked loop.

14. The method of claim 12, further comprising activating a charge pump with the first output.

15. The method of claim 14, further comprising a current source within the charge pump to receive the first output.

16. The method of claim 14, further comprising activating a current sink within the charge pump with the second output.

17. The method of claim 12, further comprising filtering an output of the charge pump.

18. The method of claim 12, further comprising delaying the phased difference pulse before it is steered.

19. The method of claim 12, further comprising frequency dividing the feedback signal.

20. The method of claim 12, further comprising operating the reference frequency at a frequency above 2 Giga hertz.
